(19) United States
(12) Patent Application Publication
(10) Pub. No.: US 2024/0043988 A1
(43) Pub. Date: Feb. 8, 2024

(54) GAS MIXTURE AS CO-GAS FOR ION IMPLANT

(71) Applicant: ENTEGRIS, INC., Billerica, MA (US)

(72) Inventors: Ying Tang, Brookfield, CT (US); Joseph R. Despres, Middletown, CT (US); Edward E. Jones, Woodbury, CT (US); Joseph D. Sweeney, New Milford, CT (US)

(21) Appl. No.: 18/216,330

(22) Filed: Jun. 29, 2023

Related U.S. Application Data
(60) Provisional application No. 63/395,583, filed on Aug. 5, 2022.

(51) Int. Cl. C23C 14/48; C23C 14/00; C23C 14/34

(52) U.S. Cl. CPC C23C 14/48; C23C 14/0057; C23C 14/0063; C23C 14/3414

(57) ABSTRACT

The present disclosure relates to an ion implantation tool source and gas delivery system. The system can include a gas source comprising one or more gas supply vessels, an ion implanter arc chamber connected to the gas source, and a gallium target contained within the ion implanter arc chamber. The one or more gas supply vessels can supply a mixture of gases of hydrogen and fluoride. The hydrogen can be from 5% to 60% of the mixture of gases.

### FIELD

The present disclosure relates to ion implantation. More specifically, the present disclosure relates to using a gas mixture as co-gas for an implant, such as a gallium implant.

### BACKGROUND

Ion implantation can be used in the manufacturing of semiconductor devices.

### SUMMARY

The present disclosure relates to using a gas mixture as co-gas for an implant, such as a gallium implant. In some embodiments, the gas mixture can include using boron trifluoride (BF3)/hydrogen (H2) or other fluoride gas and hydrogen mixture as co-gas for gallium implant. In some embodiments, the gallium implant can be performed by using gallium containing sputtering targets, such as gallium nitride (GaN), gallium oxide (Ga2O3), an isotopically enriched analog of gallium nitride (GaN) or gallium oxide (Ga2O3) comprising gallium isotopically enriched above natural abundance in 69Ga or 71Ga, or a combination thereof. Fluoride co-gas is sometimes used to enhance the gallium ion (Ga+) beam current. One potential drawback of fluoride gas is that fluoride gas can react with the arc chamber (e.g., tungsten arc chamber), thereby causing tungsten deposition on the arc chamber and electrode areas (e.g., the cathode). In some examples, tungsten deposition can degrade the source conditions and affect the source life.

The present disclosure uses boron trifluoride (BF₃) and/or hydrogen (H₂) or other fluoride gas and hydrogen mixture as co-gas for gallium containing sputtering targets, such as GaN or Ga₂O₃. In some embodiments, the hydrogen mixture will help to reduce the halogen cycle and tungsten deposition thus enhancing the source life.

In some aspects, the techniques described herein relate to an ion implantation tool source and gas delivery system: a gas source including one or more gas supply vessels, wherein the one or more gas supply vessels are configured to supply a mixture of gases including hydrogen and fluoride, wherein hydrogen includes from 5% to 60% of the mixture of gases; an ion implanter arc chamber connected to the gas source; and a gallium target contained within the ion implanter arc chamber.

In some aspects, the techniques described herein relate to an ion implantation tool source and gas delivery system, wherein the gallium target includes gallium nitride (GaN) or gallium oxide (Ga₂O₃).

In some aspects, the techniques described herein relate to an ion implantation tool source and gas delivery system, wherein the hydrogen includes hydrogen (H₂), phosphine (PH₃), AsH₃, SiH₄, B₂H₆, CH₄, NH₃, GeH₄, or a combination thereof.

In some aspects, the techniques described herein relate to an ion implantation tool source and gas delivery system, wherein the hydrogen includes hydrogen (H₂).

In some aspects, the techniques described herein relate to an ion implantation tool source and gas delivery system, wherein the hydrogen is generated from a hydrogen (H₂) generator.

In some aspects, the techniques described herein relate to an ion implantation tool source and gas delivery system, wherein the hydrogen is not from a gas supply vessel.

In some aspects, the techniques described herein relate to an ion implantation tool source and gas delivery system, wherein the fluoride includes F2 (fluorine), BF3 (boron trifluoride), SiF4 (silicon tetrafluoride), GeF4 (silicon tetrafluoride), PF3 (phosphorous trifluoride), PF5 (phosphorous pentafluoride), XeF2, CF4, CHF3, SF6, NF3, WF6, B2F4, Si2F6, or a combination thereof.

In some aspects, the techniques described herein relate to an ion implantation tool source and gas delivery system, wherein the fluoride includes BF3 (boron trifluoride).

In some aspects, the techniques described herein relate to an ion implantation tool source and gas delivery system, wherein the BF₃ (boron trifluoride) is natural BF₃ (boron trifluoride).

In some aspects, the techniques described herein relate to an ion implantation tool source and gas delivery system, wherein the BF3 (boron trifluoride) is enriched BF3 (boron trifluoride).

In some aspects, the techniques described herein relate to an ion implantation tool source and gas delivery system, wherein the mixture of gases consists essentially of BF3 (boron trifluoride) and hydrogen (H2).

In some aspects, the techniques described herein relate to an ion implantation tool source and gas delivery system, wherein a gas line connects the ion implanter arc chamber to the gas source.

In some aspects, the techniques described herein relate to an ion implantation tool source and gas delivery system, wherein hydrogen includes from 10% to 40% of the mixture of gasses.

In some aspects, the techniques described herein relate to an ion implantation tool source and gas delivery system, wherein hydrogen includes from 15% to 35% of the mixture of gasses.

In some aspects, the techniques described herein relate to a method of forming gallium ion, the method including: supplying a mixture of gases from a gas source to an ion implanter arc chamber; wherein the mixture of gases includes hydrogen and fluoride, and wherein hydrogen includes from 5% to 60% of the mixture of gases; contacting the mixture of gases to a gallium target contained within the ion implanter arc chamber.

In some aspects, the techniques described herein relate to a method, wherein the gallium target includes gallium nitride (GaN) or gallium oxide (Ga2O3).

In some aspects, the techniques described herein relate to a method, wherein the hydrogen includes hydrogen (H2), phosphine (PH3), AsH3, SiH4, B2H6, CH4, NH3, GeH4, or a combination thereof.

In some aspects, the techniques described herein relate to a method, wherein the hydrogen includes hydrogen (H₂).

In some aspects, the techniques described herein relate to a method, wherein the hydrogen is generated from a hydrogen (H2) generator.

In some aspects, the techniques described herein relate to a method, wherein the hydrogen is not from a gas supply vessel.

In some aspects, the techniques described herein relate to a method, wherein the fluoride includes F2 (fluorine), BF3 (boron trifluoride), SiF4 (silicon tetrafluoride), GeF4 (silicon tetrafluoride), PF3 (phosphorous trifluoride), PF5 (phosphorous pentafluoride), XeF2, CF4, CHF3, SF6, NF3, WF6, B2F4, Si2F6, or a combination thereof.

In some aspects, the techniques described herein relate to a method, wherein the fluoride includes BF3 (boron trifluoride).

In some aspects, the techniques described herein relate to a method, wherein the BF₃ (boron trifluoride) is natural BF₃ (boron trifluoride).

In some aspects, the techniques described herein relate to a method, wherein the BF₃ (boron trifluoride) is enriched BF₃ (boron trifluoride).

In some aspects, the techniques described herein relate to a method, wherein the mixture of gases consists essentially of BF₃ (boron trifluoride) and hydrogen (H₂).

In some aspects, the techniques described herein relate to a method, wherein a gas line connects the ion implanter arc chamber to the gas source.

In some aspects, the techniques described herein relate to a method, wherein hydrogen includes from 10% to 40% of the mixture of gasses.

In some aspects, the techniques described herein relate to a method, wherein hydrogen includes from 15% to 35% of the mixture of gasses.

### DRAWINGS

Some embodiments of the disclosure are herein described, by way of example only, with reference to the accompanying drawings. With specific reference now to the drawings in detail, it is stressed that the embodiments shown are by way of example and for purposes of illustrative discussion of embodiments of the disclosure. In this regard, the description taken with the drawings makes apparent to those skilled in the art how embodiments of the disclosure may be practiced.

FIG. 1 depicts an ion implantation tool source and gas delivery system.

FIG. 2 depicts a flowchart of a method of forming a gallium ion.

FIG. 3 depicts the Ga+ beam based on the H2 percentage in the BF3/H2 mixture on a GaN target.

FIG. 4 depicts the tungsten beam based on the percentage of the hydrogen (H2) on a GaN target.

FIG. 5 depicts the Ga+ beam based on the H2 percentage in the BF3/H2 mixture on a Ga2O3 current.

FIG. 6 depicts the tungsten beam based on the percentage of H2 on a Ga2O3 target.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure are intended to be illustrative, and not restrictive.

All prior patents and publications referenced herein are incorporated by reference in their entireties.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though they may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

As used herein, the term “between” does not necessarily require being disposed directly next to other elements. Generally, this term means a configuration where something is sandwiched by two or more other things. At the same time, the term “between” can describe something that is directly next to two opposing things. Accordingly, in any one or more of the embodiments disclosed herein, a particular structural component being disposed between two other structural elements can be:
disposed directly between both of the two other structural elements such that the particular structural component is in direct contact with both of the two other structural elements;
disposed directly next to only one of the two other structural elements such that the particular structural component is in direct contact with only one of the two other structural elements;
disposed indirectly next to only one of the two other structural elements such that the particular structural component is not in direct contact with only one of the two other structural elements, and there is another element which juxtaposes the particular structural component and the one of the two other structural elements;
disposed indirectly between both of the two other structural elements such that the particular structural component is not in direct contact with both of the two other structural elements, and other features can be disposed therebetween; or any combination(s) thereof.

As used herein “embedded” means that a first material is distributed throughout a second material.

The present disclosure relates to using a gas mixture as co-gas for an implant, such as a gallium implant. In some embodiments, the gas mixture can include using BF₃/H₂ or other fluoride gas and hydrogen mixture as co-gas for gallium implant. In some embodiments, the gallium implant can be performed by using gallium containing sputtering targets, such as GaN or Ga₂O₃.

In other embodiments the gallium implant can be performed by using gallium containing sputtering targets that include but not limited, gallium fluoride, gallium chloride, gallium bromide, gallium iodide, gallium nitride, gallium oxide, gallium arsenide, gallium phosphide, trimethylgallium Ga(CH3)3, gallium nitrate Ga(NO3)3, gallium hydroxide Ga(OH)3, gallium antimonide GaSb, gallium sulfide, gallium selenide, gallane, trihydridogallium CH3, digallane Ga2H6, gallium telluride GaTe, indium gallium phosphide, gallium arsenide phosphide, indium gallium arsenide, aluminium gallium arsenide, and/or gallium.

Fluoride co-gas is sometimes used to enhance the gallium ion (Ga+) beam current. One potential drawback of fluoride gas is that fluoride gas can react with the ion implanter arc chamber (e.g., tungsten arc chamber), thereby causing tungsten deposition on the ion implanter arc chamber and electrode areas (e.g., the cathode). In some examples, tungsten deposition can degrade the source conditions and affect the source life.

The present disclosure uses BF₃/H₂ or other fluoride gas and hydrogen mixture as co-gas for gallium containing sputtering targets, such as GaN or Ga₂O₃. In some embodiments, the hydrogen mixture will help to reduce the halogen cycle and tungsten deposition thus enhancing the source life. In some embodiments, depending on the H₂ percentage in the mixture, the tungsten ion beam (W+ beam) reduction can be at least 25%, in other instances, at least 35%, in other instances 45%, and in other instances 55%. The reduction of the tungsten ion in the plasma indicates that less tungsten deposition, and therefore increases the source life. In relevant and related application, the amount of tungsten ion brought into the gas phase and plasma during an ion implantation process, the greater the tungsten deposition or coating inside and/or around the arch chamber. The described invention herein, shows how the mixture at certain concentrations, and with the sputtering target including gallium, can reduce the deposition and enhance the source life.

Instead of the fluoride reacting with the ion implanter arc chamber, hydrogen bonds with the fluoride, thereby intercepting the reaction of fluoride and the ion implanter arc chamber. For example, when the ion implanter arc chamber is a tungsten arc chamber, fluoride intercepts the reaction between fluoride and the tungsten arc chamber, thereby reducing tungsten deposition on the ion implanter arc chamber and electrode areas (e.g., the cathode). In some embodiments, the reduction of tungsten on the ion implanter arc chamber can increase the lifetime and/or reduce the maintenance of the ion implanter arc chamber.

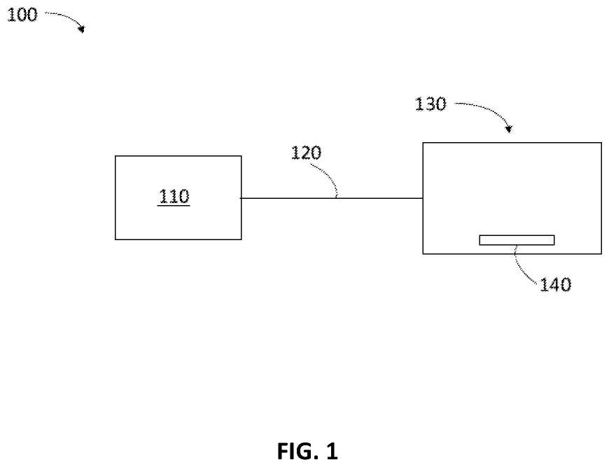

FIG. 1 depicts an ion implantation tool source and gas delivery system 100. In some embodiments, the ion implantation tool source and gas delivery system 100 includes a gas source 110, a gas line 120 and an ion implanter arc chamber 130. The ion implanter arc chamber 130 is connected to the gas source 110. In some embodiments, the gas line 120 connects the ion implanter arc chamber 130 to the gas source 110. In some embodiments, a target 140 (e.g., a gallium target) is contained within the ion implanter arc chamber 130.

In some embodiments, the target 140 is a gallium target and includes gallium nitride (GaN), gallium oxide (Ga₂O₃), GaCl₃, GaF₃ or GaₓZ_{y}, where x and y are numbers that can be 1, 2, 3, 4, 5 or 6. The “Z” represents any element.

In some embodiments, the gas source 110 includes one or more gas supply vessels. In some embodiments, the gas source 110 supplies gas at sub-atmospheric pressures. In some embodiments, the one or more gas supply vessels are configured to supply a mixture of gases comprising hydrogen and fluoride. In some embodiments, hydrogen comprises from 5% to 60% of the mixture of gases. In some embodiments, hydrogen comprises from 10% to 40% of the mixture of gasses. In some embodiments, hydrogen comprises from 15% to 35% of the mixture of gasses. In some embodiments, hydrogen of the mixture of gases comprises from 5% to 60%, 5% to 55%, 5% to 50%, 5% to 45%, 5% to 40%, 5% to 35%, 5% to 30%, 5% to 25%, 5% to 20%, 5% to 15%, 5% to 10%, 10% to 60%, 15% to 60%, 20% to 60%, 25% to 60%, 30% to 60%, 35% to 60%, 40% to 60%, 45% to 60%, 50% to 60%, or any range or subrange therebetween. In other embodiments the range of the hydrogen in the mixture can range from 13%-60%, 13% to 50%, 13% to 35%, 13% to 33%, 33% to 60%., 33% to 50%, 33% to 35% or any range or sub range therebetween.

In some embodiments, the one or more gas supply vessels can include one or more gas cylinders. In some embodiments, the mixture of gases of the present disclosure can be pre-mixed inside the same gas cylinder. The mixture of gases of the present disclosure can also be co-flowed from different cylinders. The mixture of gases of the present disclosure can also be the combination of a pre-mixed gas cylinder and co-flows with other cylinder(s). For example, in some embodiments, BF₃ can be pre-mixed with H₂ in one cylinder. In some embodiments, the hydrogen is not from a gas supply vessel. In some embodiments, the hydrogen is generated from a hydrogen (H₂) generator. In some embodiments, BF₃ can be co-flowed with H₂ in a separate H₂ gas cylinder or H₂ generator.

In some embodiments, the hydrogen of the mixture of gases comprises hydrogen (H₂), phosphine (PH₃), AsH₃, SiH₄, B₂H₆, CH₄, NH₃, GeH₄, or a combination thereof. For example, the hydrogen of the mixture gases can include hydrogen (H₂). For example, the hydrogen of the mixture gases comprises hydrogen (H₂), phosphine (PH₃), and AsH₃.

In some embodiments, the fluoride of the mixture of gases includes F₂ (fluorine), BF₃ (boron trifluoride), SiF₄ (silicon tetrafluoride), GeF₄ (silicon tetrafluoride), PF₃ (phosphorous trifluoride), PF₅ (phosphorous pentafluoride), XeF₂, CF₄, CHF₃, SF₆, NF₃, WF₆, B₂F₄, Si₂F₆, or a combination thereof. For example, the fluoride of the mixture of gases includes BF₃ (boron trifluoride). For example, the fluoride of the mixture of gases includes F₂ (fluorine), BF₃ (boron trifluoride), SiF₄ (silicon tetrafluoride).

The mixture of gases can include any combination of hydrogen described in the present disclosure and fluoride described in the present disclosure. For example, in some embodiments, the mixture of gases can include SiH₄, B₂H₆, NF₃, and WF₆. In some embodiments, the mixture of gases comprises, consists essentially of, or consists of BF₃ (boron trifluoride) and hydrogen (H₂).

In some embodiments, the BF₃ (boron trifluoride) is natural BF₃ (boron trifluoride). In some embodiments, the BF₃ (boron trifluoride) is enriched BF₃ (boron trifluoride).

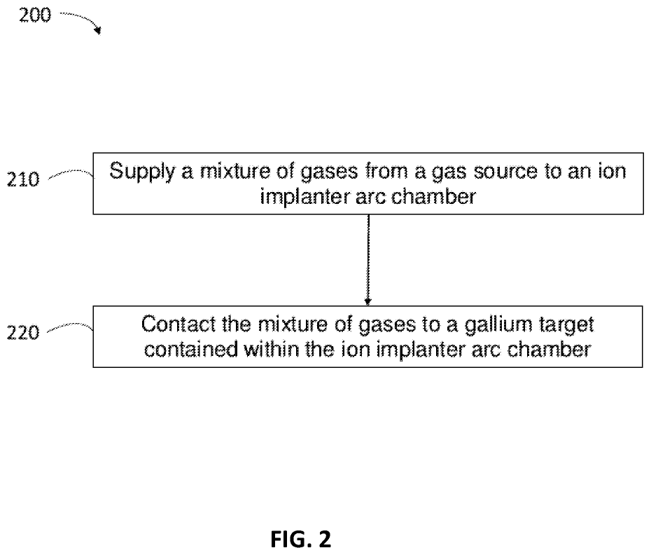

FIG. 2 depicts a flowchart of a method 200 of forming gallium ion. In some embodiments, the method 200 includes supplying 210 a mixture of gases from a gas source to an ion implanter arc chamber. In some embodiments, the method 200 further includes contacting 220 the mixture of gases to a gallium target contained within the ion implanter arc chamber. The mixture of gases, the gas source, the ion implanter arc chamber, target (e.g., gallium target) can be any of the embodiments described herein.

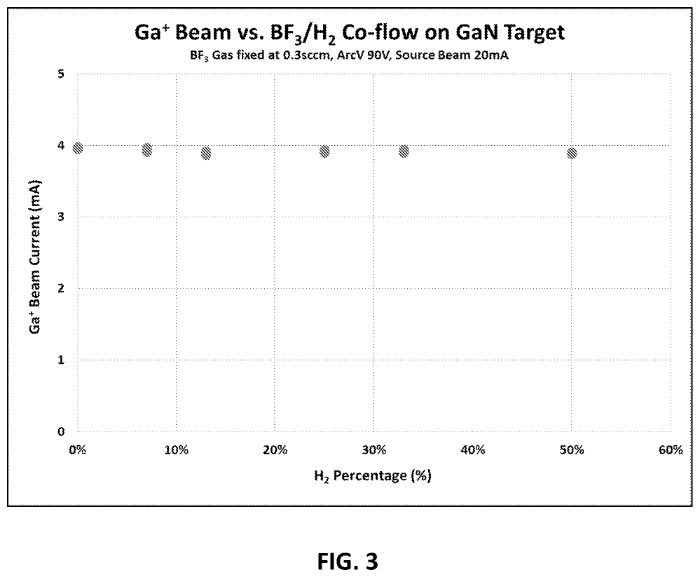

FIG. 3 depicts the stability of the Ga+ beam current at a range of 0-50% of when flowing the BF₃/H₂ on the GaN target.

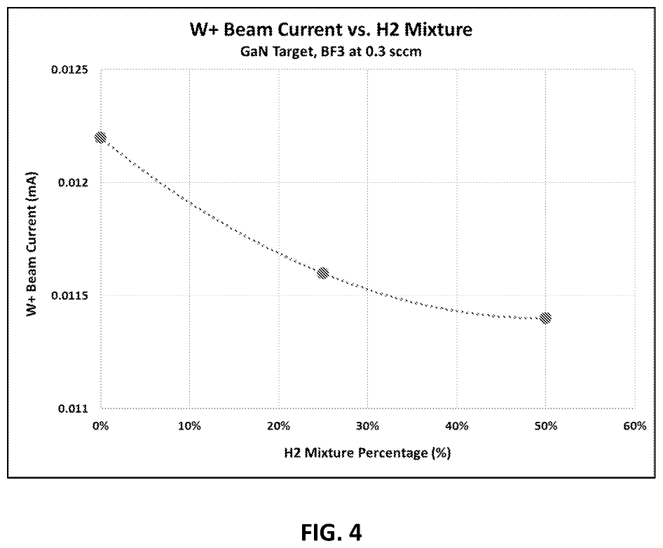

FIG. 4 shows the W+ beam reduction verses the percentage of hydrogen in the mixture. As expected, the tungsten beam drops quickly from 0-33% and starts to level off after the 33% of the mixture.

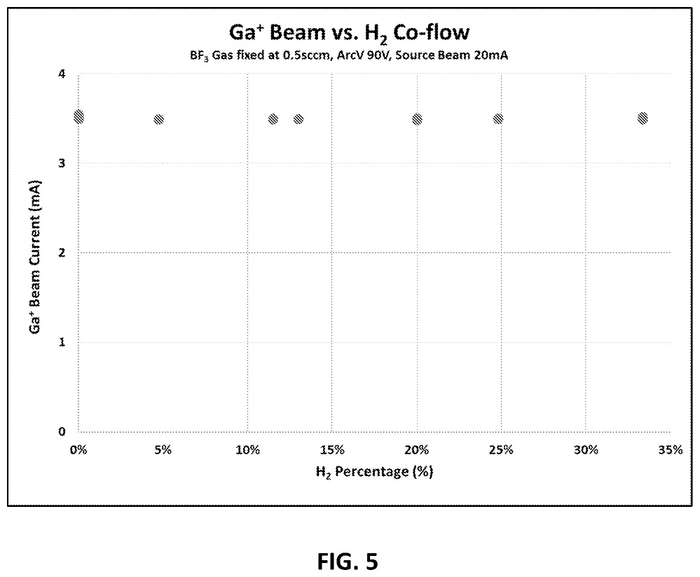

FIG. 5 depicts the stability of the Ga+ beam current at a range of 0-50% of when flowing the BF₃/H₂ on the Ga₂O₃ target.

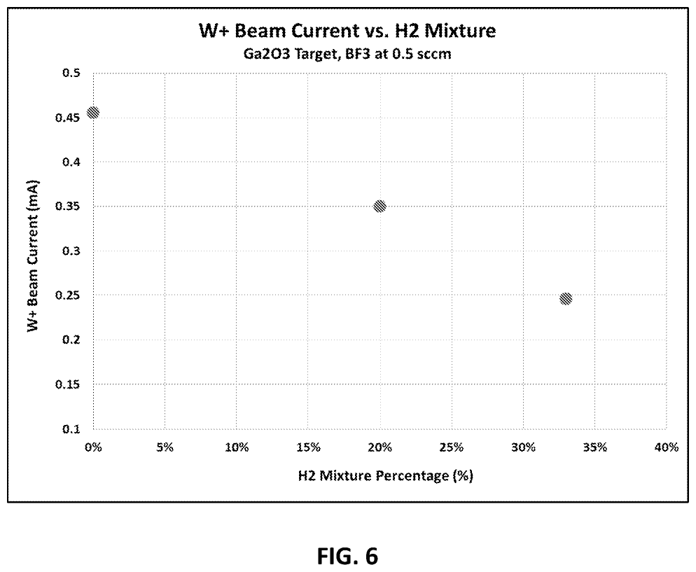

FIG. 6 shows the W+ beam reduction verses the percentage of hydrogen in the mixture. As expected, the tungsten ion beam drops quickly from 0-33% and starts to level off after the 33% of the mixture. As shown in FIG. 6, there is approximately 46% drop in the tungsten ion beam in the plasma from 0% of H₂ to 33% of H₂. Hence this reduction is correlated with enhanced source life of the gas.

### Aspects

Various Aspects are described below. It is to be understood that any one or more of the features recited in the following Aspect(s) can be combined with any one or more other Aspect(s).

Aspect 1. An ion implantation tool source and gas delivery system: a gas source comprising one or more gas supply vessels, wherein the one or more gas supply vessels are configured to supply a mixture of gases comprising hydrogen and fluoride, wherein hydrogen comprises from 5% to 60% of the mixture of gases; an ion implanter arc chamber connected to the gas source; and a gallium target contained within the ion implanter arc chamber.

Aspect 2. The ion implantation tool source and gas delivery system of Aspect 1, wherein the gallium target comprises gallium nitride (GaN) or gallium oxide (Ga₂O₃).

Aspect 3. The ion implantation tool source and gas delivery system of Aspect 1 or Aspect 2, wherein the hydrogen comprises hydrogen (H₂), phosphine (PH₃), AsH₃, SiH₄, B₂H₆, CH₄, NH₃, GeH₄, or a combination thereof.

Aspect 4. The ion implantation tool source and gas delivery system as in any of the preceding Aspects, wherein the hydrogen comprises hydrogen (H₂).

Aspect 5. The ion implantation tool source and gas delivery system as in any of the preceding Aspects, wherein the hydrogen is generated from a hydrogen (H₂) generator.

Aspect 6. The ion implantation tool source and gas delivery system as in any of the preceding Aspects, wherein the hydrogen is not from a gas supply vessel.

Aspect 7. The ion implantation tool source and gas delivery system as in any of the preceding Aspects, wherein the fluoride comprises F₂ (fluorine), BF₃ (boron trifluoride), SiF₄ (silicon tetrafluoride), GeF₄ (silicon tetrafluoride), PF₃ (phosphorous trifluoride), PF₅ (phosphorous pentafluoride), XeF₂, CF₄, CHF₃, SF₆, NF₃, WF₆, B₂F₄, Si₂F₆, or a combination thereof.

Aspect 8. The ion implantation tool source and gas delivery system as in any of the preceding Aspects 1, wherein the fluoride comprises BF₃ (boron trifluoride).

Aspect 9. The ion implantation tool source and gas delivery system of Aspect 8, wherein the BF₃ (boron trifluoride) is natural BF₃ (boron trifluoride).

Aspect 10. The ion implantation tool source and gas delivery system of Aspect 8, wherein the BF₃ (boron trifluoride) is enriched BF₃ (boron trifluoride).

Aspect 11. The ion implantation tool source and gas delivery system as in any of the preceding Aspects, wherein the mixture of gases consists essentially of BF₃ (boron trifluoride) and hydrogen (H₂).

Aspect 12. The ion implantation tool source and gas delivery system as in any of the preceding Aspects, wherein a gas line connects the ion implanter arc chamber to the gas source.

Aspect 13. The ion implantation tool source and gas delivery system as in any of the preceding Aspects, wherein hydrogen comprises from 10% to 40% of the mixture of gasses.

Aspect 14. The ion implantation tool source and gas delivery system of claim 1, wherein hydrogen comprises from 15% to 35% of the mixture of gasses.

Aspect 15. A method of forming gallium ion, the method comprising: supplying a mixture of gases from a gas source to an ion implanter arc chamber; wherein the mixture of gases comprises hydrogen and fluoride, and wherein hydrogen comprises from 5% to 60% of the mixture of gases; and contacting the mixture of gases to a gallium target contained within the ion implanter arc chamber.

Aspect 16. The method of Aspect 15, wherein the gallium target comprises gallium nitride (GaN) or gallium oxide (Ga₂O₃).

Aspect 17. The method of Aspect 15 or Aspect 16, wherein the hydrogen comprises hydrogen (H₂), phosphine (PH₃), AsH₃, SiH₄, B₂H₆, CH₄, NH₃, GeH₄, or a combination thereof.

Aspect 18. The method as in any of the preceding Aspects, wherein the hydrogen comprises hydrogen (H₂).

Aspect 19. The method as in any of the preceding Aspects, wherein the hydrogen is generated from a hydrogen (H₂) generator.

Aspect 20. The method as in any of the preceding Aspects, wherein the hydrogen is not from a gas supply vessel.

Aspect 21. The method as in any of the preceding Aspects, wherein the fluoride comprises F₂ (fluorine), BF₃ (boron trifluoride), SiF₄ (silicon tetrafluoride), GeF₄ (silicon tetrafluoride), PF₃ (phosphorous trifluoride), or PF6 (phosphorous pentafluoride), XeF₂, CF₄, CHF₃, SF₆, NF₃, WF₆, B₂F₄, Si₂F₆, or a combination thereof.

Aspect 22. The method as in any of the preceding Aspects, wherein the fluoride comprises BF₃ (boron trifluoride).

Aspect 23. The method of Aspect 22, wherein the BF₃ (boron trifluoride) is natural BF₃ (boron trifluoride).

Aspect 24. The method of Aspect 22, wherein the BF₃ (boron trifluoride) is enriched BF₃ (boron trifluoride).

Aspect 25. The method as in any of the preceding Aspects, wherein the mixture of gases consists essentially of BF₃ (boron trifluoride) and hydrogen (H₂).

Aspect 26. The method as in any of the preceding Aspects, wherein a gas line connects the ion implanter arc chamber to the gas source.

Aspect 27. The method as in any of the preceding Aspects, wherein hydrogen comprises from 10% to 40% of the mixture of gasses.

Aspect 28. The method as in any of the preceding Aspects, wherein hydrogen comprises from 15% to 35% of the mixture of gasses.

Aspect 29. The method as in any of the preceding Aspects, wherein the gallium target comprises at least one of the following: gallium fluoride, gallium chloride, gallium bromide, gallium iodide, gallium nitride, gallium oxide, gallium arsenide, gallium phosphide, trimethylgallium Ga(CH3)3, gallium nitrate Ga(NO3)3, gallium hydroxide Ga(OH)3, gallium antimonide GaSb, gallium sulfide, gallium selenide, gallane, trihydridogallium CH3, digallane Ga2H6, gallium telluride GaTe, indium gallium phosphide, gallium arsenide phosphide, indium gallium arsenide, aluminium gallium arsenide, and/or gallium

It is to be understood that changes may be made in detail, especially in matters of the construction materials employed and the shape, size, and arrangement of parts without departing from the scope of the present disclosure. This Specification and the embodiments described are examples, with the true scope and spirit of the disclosure being indicated by the claims that follow.

What is claimed is:

1. An ion implantation tool source and gas delivery system:
a gas source comprising one or more gas supply vessels, wherein the one or more gas supply vessels are configured to supply a mixture of gases comprising hydrogen and fluoride, wherein hydrogen comprises from 5% to 60% of the mixture of gases;
an ion implanter arc chamber connected to the gas source; and
a gallium target contained within the ion implanter arc chamber.

2. The ion implantation tool source and gas delivery system of claim 1, wherein the gallium target comprises gallium nitride (GaN) or gallium oxide (Ga₂O₃).

3. The ion implantation tool source and gas delivery system of claim 1, wherein the gallium target comprises at least one of the following: gallium fluoride, gallium chloride, gallium bromide, gallium iodide, gallium nitride, gallium oxide, gallium arsenide, gallium phosphide, trimethylgallium Ga(CH3)3, gallium nitrate Ga(NO3)3, gallium hydroxide Ga(OH)3, gallium antimonide GaSb, gallium sulfide, gallium selenide, gallane, trihydridogallium CH3, digallane Ga2H6, gallium telluride GaTe, indium gallium phosphide, gallium arsenide phosphide, indium gallium arsenide, aluminium gallium arsenide, and/or gallium.

4. The ion implantation tool source and gas delivery system of claim 1, wherein the hydrogen comprises hydrogen (H₂), phosphine (PH₃), AsH₃, SiH₄, B₂H₆, CH₄, NH₃, GeH₄, or a combination thereof.

5. The ion implantation tool source and gas delivery system of claim 1, wherein the hydrogen comprises hydrogen (H₂).

6. The ion implantation tool source and gas delivery system of claim 1, wherein the fluoride comprises F₂ (fluorine), BF₃ (boron trifluoride), SiF₄ (silicon tetrafluoride), GeF₄ (silicon tetrafluoride), PF₃ (phosphorous trifluoride), PF6 (phosphorous pentafluoride), XeF₂, CF₄, CHF₃, SF₆, NF₃, WF₆, B₂F₄, Si₂F₆, or a combination thereof.

7. The ion implantation tool source and gas delivery system of claim 1, wherein the fluoride comprises BF₃ (boron trifluoride) or enriched BF₃ (boron trifluoride).

8. The ion implantation tool source and gas delivery system of claim 1, wherein the mixture of gases consists essentially of BF₃ (boron trifluoride) and hydrogen (H₂).

9. The ion implantation tool source and gas delivery system of claim 1, wherein hydrogen comprises from 10% to 40% of the mixture of gasses.

10. The ion implantation tool source and gas delivery system of claim 1, wherein hydrogen comprises from 15% to 35% of the mixture of gasses.

11. A method of forming gallium ion, the method comprising:
supplying a mixture of gases from a gas source to an ion implanter arc chamber, wherein the mixture of gases comprises hydrogen and fluoride, and wherein hydrogen comprises from 5% to 60% of the mixture of gases; and
contacting the mixture of gases to a gallium target contained within the ion implanter arc chamber.

12. The method of claim 11, wherein the gallium target comprises gallium nitride (GaN) or gallium oxide (Ga₂O₃).

13. The method of claim 11, wherein the gallium target comprises at least one of the following: gallium fluoride, gallium chloride, gallium bromide, gallium iodide, gallium nitride, gallium oxide, gallium arsenide, gallium phosphide, trimethylgallium Ga(CH3)3, gallium nitrate Ga(NO3)3, gallium hydroxide Ga(OH)3, gallium antimonide GaSb, gallium sulfide, gallium selenide, gallane, trihydridogallium CH3, digallane Ga2H6, gallium telluride GaTe, indium gallium phosphide, gallium arsenide phosphide, indium gallium arsenide, aluminium gallium arsenide, and/or gallium.

14. The method of claim 11, wherein the hydrogen comprises hydrogen (H₂), phosphine (PH₃), AsH₃, SiH₄, B₂H₆, CH₄, NH₃, GeH₄, or a combination thereof.

15. The method of claim 11, wherein the hydrogen comprises hydrogen (H₂).

16. The method of claim 11, wherein the fluoride comprises F₂ (fluorine), BF₃ (boron trifluoride), SiF₄ (silicon tetrafluoride), GeF₄ (silicon tetrafluoride), PF₃ (phosphorous trifluoride), or PF₅ (phosphorous pentafluoride), XeF₂, CF₄, CHF₃, SF₆, NF₃, WF₆, B₂F₄, Si₂F₆, or a combination thereof.

17. The method of claim 16, wherein the BF₃ (boron trifluoride) is natural BF₃ (boron trifluoride).

18. The method of claim 11, wherein the mixture of gases consists essentially of BF₃ (boron trifluoride) and hydrogen (H₂).

19. The method of claim 11, wherein hydrogen comprises from 10% to 40% of the mixture of gasses.

20. The method of claim 11, wherein hydrogen comprises from 15% to 35% of the mixture of gasses.
